(19) United States
(12) Patent Application Publication
(10) Pub. No.: US 2017/0170280 A1
(43) Pub. Date: Jun. 15, 2017

(54) METHOD AND APPARATUS FOR MANUFACTURING SEMICONDUCTOR ELEMENT, AND SEMICONDUCTOR ELEMENT

(71) Applicant: SUMITOMO HEAVY INDUSTRIES, LTD., Tokyo (JP)

(72) Inventors: Naoki Wakabayshi, Kanagawa (JP); Teruhisa Kawasaki, Kanagawa (JP)

(21) Appl. No.: 15/442,339

(22) Filed: Feb. 24, 2017

Related U.S. Application Data
(63) Continuation of application No. PCT/JP2015/064146, filed on May 18, 2015.

(30) Foreign Application Priority Data
Aug. 26, 2014 (JP) 2014-171053

(51) Int. Cl. H01L 29/16; H01L 29/45; H01L 29/66; H01L 29/872; H01L 29/47; H01L 21/04; H01L 21/268

(52) U.S. Cl. CPC H01L 29/1608; H01L 21/0485; H01L 29/45; H01L 21/268; H01L 29/872; H01L 21/0495; H01L 29/47; H01L 29/6606

(57) ABSTRACT

A method for manufacturing a semiconductor element, including forming a metal film, which contains at least one metal selected from the group consisting of titanium, tungsten, molybdenum, and chromium, on a first surface of a substrate formed of silicon carbide, and forming a metal silicide film by causing a silicide reaction within an interface between the substrate and the metal film by irradiating the metal film with a pulsed laser beam having a wavelength within a range of 330 nm to 370 nm.

### RELATED APPLICATIONS

This is a continuation of International Patent Application No. PCT/JP2015/064146 filed on May 18, 2015 claiming Convention priority based on Japanese Patent Application No. 2014-171053, filed Aug. 26, 2014, and, the entire contents of each of which, including the specifications, claims and drawings, are incorporated herein by reference in their entirety.

### BACKGROUND

Technical Field

Certain embodiments of the present invention relate to a method and an apparatus for manufacturing a semiconductor element that is for forming an ohmic electrode on a silicon carbide (SiC) substrate, and the semiconductor element.

Description of Related Art

As a semiconductor material for a semiconductor power device, SiC having a bandgap wider than that of silicon is drawing attention. The power semiconductor devices using SiC such as a Schottky barrier diode, MOSFET, and JFET are being put to practical use. It is more difficult to prepare a SiC wafer having a small defect than to make a Si wafer having a small defect. Therefore, an epitaxial layer having a small defect that is formed on a SiC wafer is used as a drift layer. The thickness of the epitaxial layer is set in accordance with the required pressure resistance. In a case where SiC is used as a drift layer, the same pressure resistance can be secured by the drift layer having a thickness of about 1/10 of Si. For example, an epitaxial layer formed of SiC having a thickness of 10 μm can secure a pressure resistance approximately equivalent to a pressure resistance that a Si wafer having a thickness of 100 μm has.

In a Schottky barrier diode, an anode electrode is formed on the surface of the epitaxial layer. In a switching element, an element structure having a switching function is formed on the surface of the epitaxial layer. The SiC wafer which is a base of the epitaxial layer functions as a supporting substrate of the epitaxial layer. In order to reduce power loss, it is preferable to thin down the SiC wafer. In a case where the SiC wafer is thinned down before the element structure is formed on the surface of the epitaxial layer, due to the damage or warpage that occurs during a process, it is difficult to form the element structure. Accordingly, it is preferable to shave off and thin down the SiC wafer before the element structure is formed on the surface of the epitaxial layer.

An ohmic electrode is formed on a rear surface of the thinned SiC wafer. In a case where laser annealing is applied at the time of forming the ohmic electrode, the influence of heat exerted on the element structure formed on a front surface can be further reduced than in a case where annealing is performed using an electric furnace. As the ohmic electrode, a metal silicide such as nickel silicide is used.

The related art discloses a method for forming nickel silicide and titanium silicide on a SiC substrate. In the method of the related art, by performing laser annealing under the conditions in which a nickel film or a titanium film formed on the SiC substrate are not melted, an ohmic electrode is formed.

### SUMMARY

According to an embodiment of the present invention, there is provided a method for manufacturing a semiconductor element, including forming a metal film, which contains at least one metal selected from the group consisting of titanium, tungsten, molybdenum, and chromium, on a first surface of a substrate formed of silicon carbide, and a forming a metal silicide film by causing a silicide reaction within an interface between the substrate and the metal film by irradiating the metal film with a pulsed laser beam having a wavelength within a range of 330 nm to 370 nm, in which a thickness of the metal film is equal to or greater than 30 nm, a pulse width of the pulsed laser beam is within a range of 20 ns to 200 ns, and a fluence is selected so as to satisfy conditions under which a maximum temperature of a surface of the metal film does not exceed a melting point of the metal film, and a maximum temperature of the interface between the metal film and the substrate becomes equal to or higher than a silicide reaction temperature of the metal film.

According to another embodiment of the present invention, there is provided a semiconductor element including a substrate formed of silicon carbide, a metal film which is formed on a first surface of the substrate and contains at least one metal selected from the group consisting of titanium, tungsten, molybdenum, and chromium, and a metal silicide film formed by causing a silicide reaction within an interface between the substrate and the metal film by irradiating the metal film with a pulsed laser beam having a wavelength within a range of 330 nm to 370 nm, in which a thickness of the metal film is equal to or greater than 30 nm, a pulse width of the pulsed laser beam is within a range of 20 ns to 200 ns, and a fluence is selected so as to satisfy conditions under which a maximum temperature of a surface of the metal film does not exceed a melting point of the metal film and a maximum temperature of the interface between the metal film and the substrate becomes equal to or higher than a silicide reaction temperature of the metal film.

According to still another embodiment of the present invention, an apparatus for manufacturing a semiconductor element, including a metal film forming portion that forms a metal film, which contains at least one metal selected from the group consisting of titanium, tungsten, molybdenum, and chromium, on a first surface of a substrate formed of silicon carbide, and a metal silicide film forming portion that forms a metal silicide film by causing a silicide reaction within an interface between the substrate and the metal film by irradiating the metal film with a pulsed laser beam having a wavelength within a range of 330 nm to 370 nm, in which a thickness of the metal film is equal to or greater than 30 nm, a pulse width of the pulsed laser beam is within a range of 20 ns to 200 ns, and a fluence is selected so as to satisfy conditions under which a maximum temperature of a surface of the metal film does not exceed a melting point of the metal film and a maximum temperature of the interface between the metal film and the substrate becomes equal to or higher than a silicide reaction temperature of the metal film.

### BRIEF DESCRIPTION OF THE DRAWINGS

FIGS. 1A to 1D are cross-sectional views showing a substrate in the middle of a manufacturing stage of a method for manufacturing a semiconductor element in examples.

FIGS. 1E and 1F are cross-sectional views showing the substrate in the middle of the manufacturing stage of the method for manufacturing a semiconductor element in examples.

FIG. 2 is a graph showing the simulation results of a temperature change of an interface between a metal film and a substrate at the time of laser annealing performed using a Ti film having a thickness of 100 nm as the metal film.

FIGS. 3A to 3D are SEM images of a cross-section and a surface of a substrate having undergone laser annealing under the conditions of a fluence of 1.2 J/cm², 1.4 J/cm², 1.6 J/cm², and 1.8 J/cm² respectively.

FIG. 4 is a graph showing the simulation results of a temperature change of a surface of a metal film that are obtained by performing simulation on the same sample as used in simulation of FIG. 2.

FIG. 5 is a cross-sectional TEM image of a substrate having undergone laser annealing under the conditions of a fluence of 2.0 J/cm².

FIGS. 6A and 6B are graphs showing the simulation results of a temporal change of an interfacial temperature between a Ti film and a SiC substrate that are obtained when laser annealing is performed under the conditions of a wavelength of 355 nm and a thickness of a Ti film of 70 nm.

FIGS. 6C and 6D are graphs showing the simulation results of a temporal change of an interfacial temperature between a Ti film and a SiC substrate that are obtained when laser annealing is performed under the conditions of a wavelength of 355 nm and a thickness of a Ti film of 70 nm.

FIG. 7 is a graph showing a range of annealing conditions under which a maximum temperature of an interface between a Ti film and a SiC substrate becomes equal to or higher than a silicide reaction temperature of Ti, and a maximum temperature of a surface of the Ti film does not exceed a melting point of Ti.

FIGS. 8A and 8B are graphs showing the simulation results of a temporal change of an interfacial temperature between a Ti film and a SiC substrate that are obtained when laser annealing is performed under the conditions of a thickness of a Ti film of 100 nm.

FIGS. 8C and 8D are graphs showing the simulation results of a temporal change of an interfacial temperature between a Ti film and a SiC substrate that are obtained when laser annealing is performed under the conditions of a thickness of a Ti film of 100 nm.

FIG. 9 is a graph showing a range of annealing conditions under which, when a thickness of a Ti film is 100 nm, a maximum temperature of an interface between the Ti film and a SiC substrate becomes equal to or higher than a silicide reaction temperature of Ti, and a maximum temperature of a surface of the Ti film does not exceed a melting point of Ti.

FIGS. 10A and 10B are graphs showing the simulation results of a temporal change of an interfacial temperature between a Ti film and a SiC substrate that are obtained when laser annealing is performed under the conditions of a thickness of a Ti film of 150 nm.

FIGS. 10C and 10D are graphs showing the simulation results of a temporal change of an interfacial temperature between a Ti film and a SiC substrate that are obtained when laser annealing is performed under the conditions of a thickness of a Ti film of 150 nm.

FIG. 11 is a graph showing a range of annealing conditions under which, when a thickness of a Ti film is 150 nm, a maximum temperature of an interface between the Ti film and a SiC substrate becomes equal to or higher than a silicide reaction temperature of Ti, and a maximum temperature of a surface of the Ti film does not exceed a melting point of Ti.

FIGS. 12A and 12B are graphs showing the simulation results of a temporal change of an interfacial temperature between a Ti film and a SiC substrate that are obtained when laser annealing is performed under the conditions of a thickness of a Ti film of 30 nm.

FIGS. 12C and 12D are graphs showing the simulation results of a temporal change of an interfacial temperature between a Ti film and a SiC substrate that are obtained when laser annealing is performed under the conditions of a thickness of a Ti film of 30 nm.

FIG. 13 is a graph showing a range of annealing conditions under which, when a thickness of a Ti film is 30 nm, a maximum temperature of an interface between the Ti film and a SiC substrate becomes equal to or higher than a silicide reaction temperature of Ti, and a maximum temperature of a surface of the Ti film does not exceed a melting point of Ti.

FIG. 14 is a graph showing the simulation results of a temperature change of an interface between a metal film and a substrate at the time of laser annealing performed using a tungsten (W) film having a thickness of 100 nm as a metal film.

FIG. 15 is a graph showing a range of annealing conditions under which, when a thickness of a W film is 70 nm, a maximum temperature of an interface between the W film and a SiC substrate becomes equal to or higher than a silicide reaction temperature of W, and a maximum temperature of a surface of the W film does not exceed a melting point of W.

FIG. 16 is a graph showing a range of annealing conditions under which, when a thickness of a W film is 100 nm, a maximum temperature of an interface between the W film and a SiC substrate becomes equal to or higher than a silicide reaction temperature of W, and a maximum temperature of a surface of the W film does not exceed a melting point of W.

FIG. 17 is a graph showing a range of annealing conditions under which, when a thickness of a W film is 150 nm, a maximum temperature of an interface between the W film and a SiC substrate becomes equal to or higher than a silicide reaction temperature of W, and a maximum temperature of a surface of the W film does not exceed a melting point of W.

FIG. 18 is a graph showing the simulation results of a temperature change of an interface between a metal film and a substrate at the time of laser annealing performed using a molybdenum (Mo) film having a thickness of 100 nm as a metal film.

FIG. 19 is a graph showing a range of annealing conditions under which, when a thickness of a Mo film is 70 nm, a maximum temperature of an interface between the Mo film and a SiC substrate becomes equal to or higher than a silicide reaction temperature of Mo, and a maximum temperature of a surface of the Mo film does not exceed a melting point of Mo.

FIG. 20 is a graph showing a range of annealing conditions under which, when a thickness of a Mo film is 100 nm, a maximum temperature of an interface between the Mo film and a SiC substrate becomes equal to or higher than a silicide reaction temperature of Mo, and a maximum temperature of a surface of the Mo film does not exceed a melting point of Mo.

FIG. 21 is a graph showing a range of annealing conditions under which, when a thickness of a Mo film is 150 nm, a maximum temperature of an interface between the Mo film and a SiC substrate becomes equal to or higher than a silicide reaction temperature of Mo, and a maximum temperature of a surface of the Mo film does not exceed a melting point of Mo.

FIG. 22 is a graph showing the simulation results of a temperature change of an interface between a metal film and a substrate at the time of laser annealing performed using a chromium (Cr) film having a thickness of 100 nm as a metal film.

FIG. 23 is a graph showing a range of annealing conditions under which, when a thickness of a Cr film is 70 nm, a maximum temperature of an interface between the Cr film and a SiC substrate becomes equal to or higher than a silicide reaction temperature of Cr, and a maximum temperature of a surface of the Cr film does not exceed a melting point of Cr.

FIG. 24 is a graph showing a range of annealing conditions under which, when a thickness of a Cr film is 100 nm, a maximum temperature of an interface between the Cr film and a SiC substrate becomes equal to or higher than a silicide reaction temperature of Cr, and a maximum temperature of a surface of the Cr film does not exceed a melting point of Cr.

FIG. 25 is a graph showing a range of annealing conditions under which, when a thickness of a Cr film is 150 nm, a maximum temperature of an interface between the Cr film and a SiC substrate becomes equal to or higher than a silicide reaction temperature of Cr, and a maximum temperature of a surface of the Cr film does not exceed a melting point of Cr.

### DETAILED DESCRIPTION

The melting point of nickel (Ni) is lower than that of titanium (Ti). Therefore, in a case where the interfacial temperature between a Ni film and a SiC substrate is increased up to a silicide reaction temperature of Ni, the temperature of the surface of the Ni film increases and becomes close to the melting point. It is difficult to find out the annealing conditions under which the surface of the nickel film is not melted, and the temperature of the interface between the nickel film and the SiC substrate becomes equal to or higher than the silicide reaction temperature of Ni. It was understood that, in a case where a Ti silicide film is formed on the SiC substrate, if a pulse width is made too short, in some cases, the Ti silicide film cannot be formed under the conditions in which the Ti film is not melted.

It is desirable to provide a method for manufacturing a semiconductor element by performing annealing under the laser annealing conditions under which a metal silicide film can be formed without melting a metal film formed on a SiC substrate.

Within the range of the aforementioned laser annealing conditions, it is easy to find out appropriate annealing conditions under which a metal silicide film can be formed without melting the metal film.

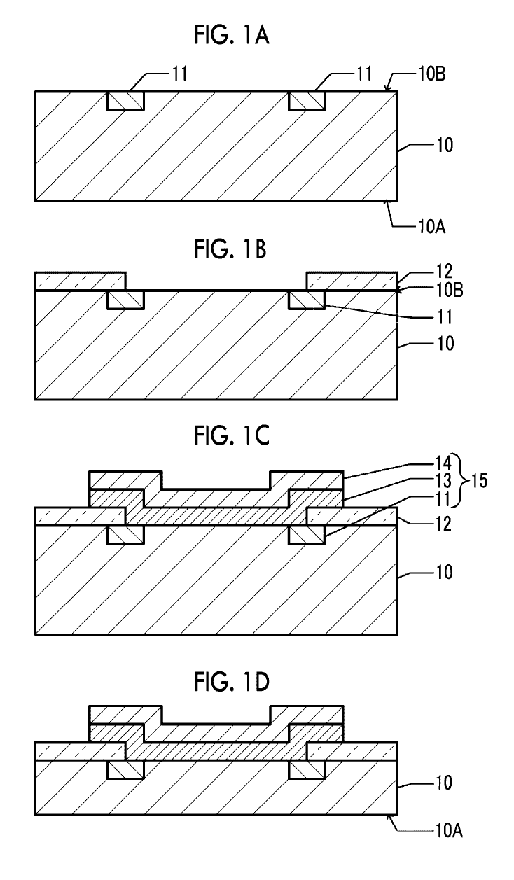

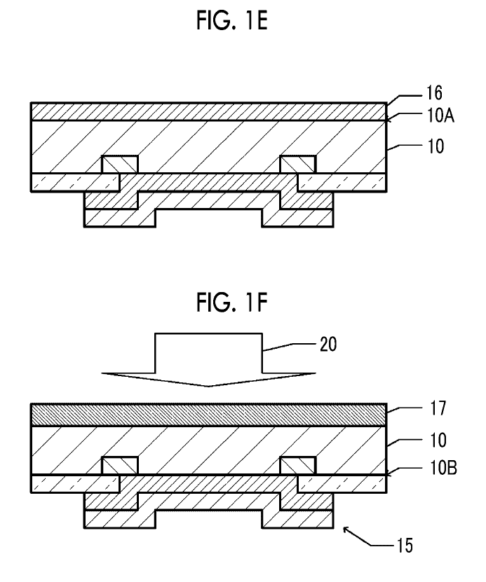

The method for manufacturing a semiconductor element performed in examples will be described with reference to FIGS. 1A to 1F.

As shown in FIG. 1A, by causing the epitaxial growth of n-type SiC on a surface of a substrate formed of n-type SiC, a substrate 10 made of SiC is formed. For the substrate 10, for example, 4H—SiC, 6H—SiC, or 3C—SiC can be used. On the portion of a surface layer of the epitaxial layer, p-type guard rings 11 are formed by ion injection. A surface on the side opposite to a surface on which the guard rings 11 are formed is called “first surface” 10A, and the surface on which the guard rings 11 are formed is called a “second surface” 10B. As shown in FIG. 1B, an insulating film 12 made of silicon oxide is formed on the second surface 10B. Within the insulating film 12, an opening through which regions surrounded by the guard rings 11 are exposed is formed.

As shown in FIG. 1C, a Schottky electrode 13 is formed on a surface of the substrate 10 that is exposed to the bottom surface of the opening formed within the insulating film 12. For example, by forming a titanium film and then performing a thermal treatment, Schottky contact is established. A surface electrode 14 is formed on the Schottky electrode 13. For the surface electrode 14, for example, aluminum is used. The guard rings 11, the Schottky electrode 13, and the surface electrode 14 are collectively called an element structure 15.

As shown in FIG. 1D, by grinding the first surface 10A of the substrate 10, the substrate 10 is thinned down. As shown in FIG. 1E, a metal film 16 is formed on the first surface 10A of the substrate 10. For the metal film 16, for example, titanium (Ti), tungsten (W), molybdenum (Mo), or chromium (Cr) is used.

As shown in FIG. 1F, laser annealing is performed by irradiating the metal film 16 with a pulsed laser beam 20. The pulsed laser beam 20 has a top-flat beam profile. The laser annealing is performed in a state where an incidence region of the pulsed laser beam 20 is being moved (scanned) within the surface of the metal film 16. An overlap rate of the incidence region is, for example, 50% to 90%. Through the laser annealing, the metal film 16 becomes silicide, and hence a metal silicide film 17 is formed. The laser annealing is performed under the conditions in which the metal film 16 is not melted. Hereinafter, the conditions under which a silicide reaction is caused without melting the metal film 16 are called a “non-melting silicide conditions”.

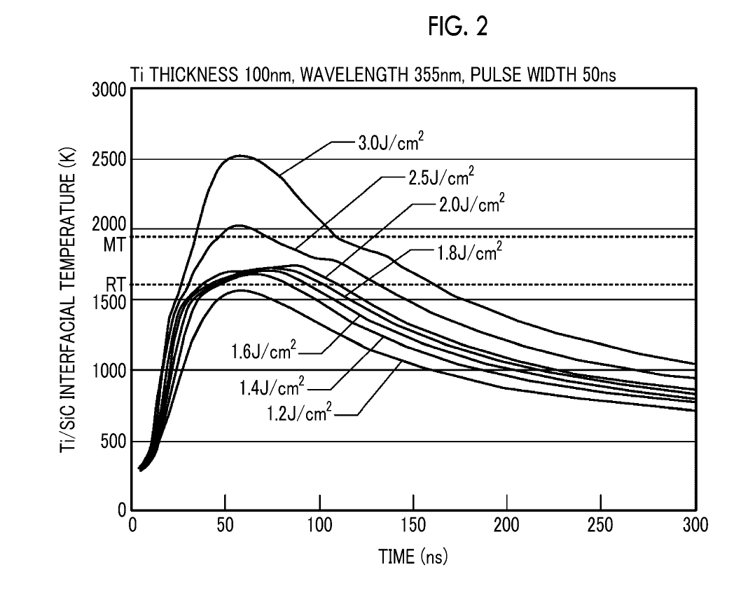

FIG. 2 shows the simulation results of a temperature change of an interface between the metal film 16 and the substrate 10 at the time of laser annealing performed using a titanium (Ti) film having a thickness of 100 nm as the metal film 16 (FIG. 1E). The abscissa shows the time elapsing from the point of a rise time of a laser pulse in the unit of “ns”, and the ordinate shows an interfacial temperature between the metal film 16 and the substrate 10 in the unit of “K”. The curves of FIG. 2 show a temperature change at the time when the laser annealing is performed under the conditions in which a fluence within the surface of the metal film 16 is, in order from the bottom curve, 1.2 J/cm², 1.4 J/cm², 1.6 J/cm², 1.8 J/cm², 2.0 J/cm², 2.5 J/cm², and 3.0 J/cm². The silicide reaction temperature RT of Ti is 1,603 K, and the melting point MT of Ti is 1,941 K. A boiling point of Ti is 3,560 K which is beyond the range that the ordinate of the graph of FIG. 2 shows. The pulsed laser beam has a wavelength of 355 nm and a pulse width of 50 ns.

It is understood that, under the conditions of a fluence of equal to or greater than 1.4 J/cm², the maximum temperature of the interface exceeds the silicide reaction temperature RT. Accordingly, presumably, by performing annealing under the conditions of a fluence of equal to or greater than 1.4 J/cm², a TI silicide film will may be formed. Furthermore, presumably, by performing annealing under the conditions of a fluence of equal to or greater than 2.5 J/cm², the maximum temperature of the interface may exceed the melting point MT, and the entirety of the Ti film in a thickness direction may be melted.

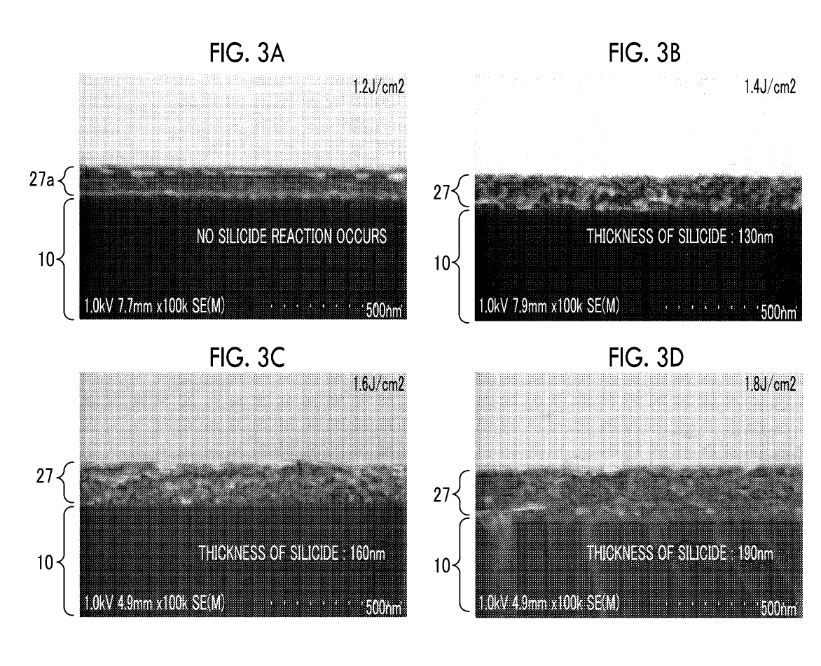

FIGS. 3A to 3D are SEM images of a cross-section and a surface of a substrate having undergone laser annealing under the conditions of a fluence of 1.2 J/cm², 1.4 J/cm², 1.6 J/cm², and 1.8 J/cm² respectively. In FIG. 3A, a crystal grain of TI silicide is not observed, and Ti film 27a remains on the substrate 10. This means that a silicide reaction did not occur. In FIGS. 3B, 3C, and 3D, Ti silicide films 27 each having a thickness of 130 nm, 160 nm, and 190 nm are formed. The results of the experiment agree with the simulation results shown in FIG. 2.

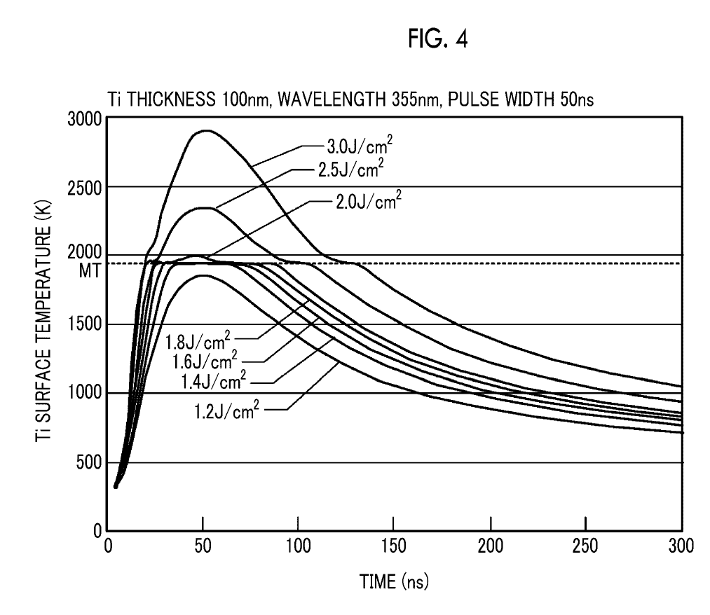

FIG. 4 shows the simulation results of a temperature change of a surface of the metal film 16 that are obtained by performing simulation under the same simulation conditions as in FIG. 2. The abscissa shows the time elapsing from the point of a rise time of a laser pulse in the unit of “ns”, and the ordinate shows a temperature of the surface of the Ti film in the unit of “K”. Similarly to FIG. 2, the curves of FIG. 4 show a temperature change at the time when the laser irradiation is performed under the conditions in which a fluence within the surface of the metal film 16 is, in order from the bottom curve, 1.2 J/cm², 1.4 J/cm², 1.6 J/cm², 1.8 J/cm², 2.0 J/cm², 2.5 J/cm², and 3.0 J/cm².

It is understood that in a case where the annealing is performed under the conditions of a fluence of equal to or greater than 2.0 J/cm², the temperature of the surface of the Ti film exceeds the melting point MT, and the Ti film is melted. Under the conditions of a fluence of equal to or less than 1.8 J/cm², the Ti film is not melted.

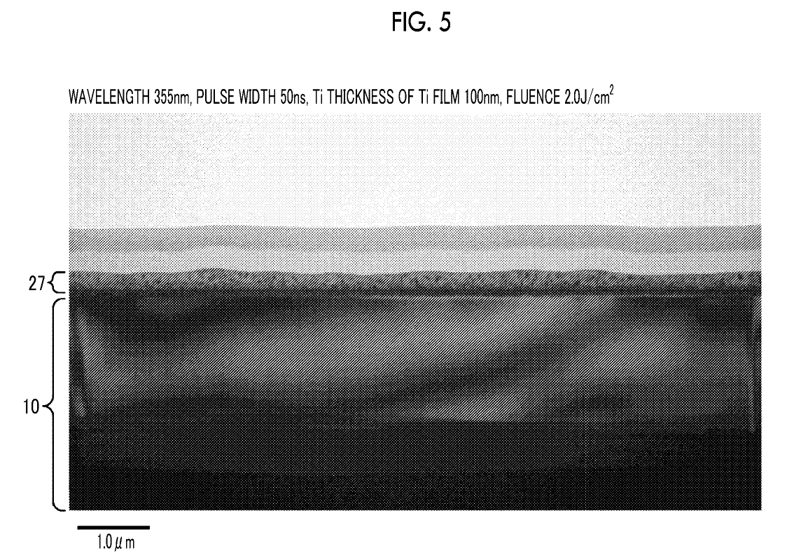

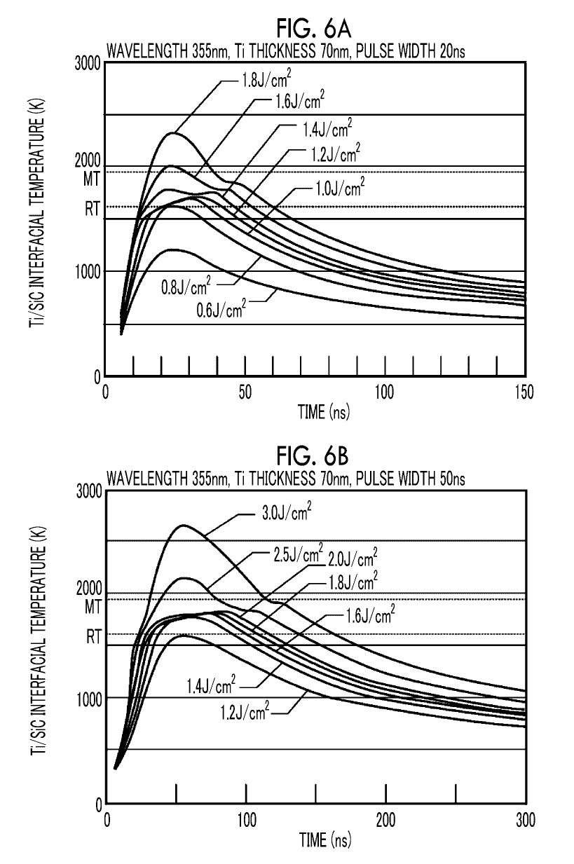

FIG. 5 is a cross-sectional TEM image of a substrate having undergone laser annealing under the conditions of a fluence of 2.0 J/cm². The Ti silicide film 27 is formed on the surface of the substrate 10 formed of SiC. On the Ti silicide film 27, a protective film for capturing a TEM image is formed. From the TEM image shown in FIG. 5, it is understood that the surface of the Ti silicide film 27 undulates. This is because the Ti film is melted at the time of the laser annealing and then solidified again. The fact that the Ti film is melted under the conditions of a fluence of 2.0 J/cm² agrees with the simulation result shown in FIG. 4.

As a result of performing laser annealing under the conditions of a fluence of 2.5 J/cm², carbon was found to be precipitated on the upper surface of the formed Ti silicide film. It is considered that this is because carbon inside the Ti film in the molten state rose to the surface. The result of the experiment agrees with the fact that the interfacial temperature exceeds the melting point MT when the fluence was 2.5 J/cm² in the simulation shown in FIG. 2.

In order to form the TI silicide film 27 having a flat surface, it is preferable to select a fluence satisfying the conditions under which the maximum temperature of the surface of the Ti film does not exceed the melting point of Ti. Furthermore, in order to cause a silicide reaction in the interface between the Ti film and the SiC substrate, it is preferable to select a fluence satisfying the conditions under which the maximum temperature of the interface becomes equal to or higher than the silicide reaction temperature of Ti.

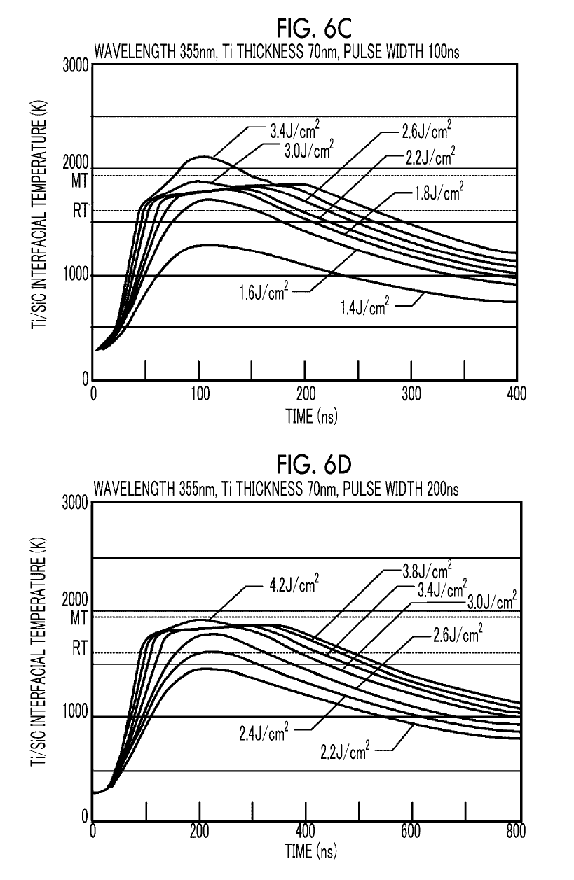

FIG. 6A to 6D each showing the simulation results of a temporal change of an interfacial temperature between a Ti film and a SiC substrate that are obtained when laser annealing is performed under the conditions of a wavelength of 355 nm and a thickness of the Ti film of 70 nm. The abscissa shows the time elapsing from the point of a rise time of a laser pulse in the unit of “ns”, and the ordinate shows an interfacial temperature in the unit of “K”. FIGS. 6A, 6B, 6C, and 6D show the simulation results obtained under the conditions of a pulse width of a pulsed laser beam of 20 ns, 50 ns, 100 ns, and 200 ns respectively.

The curves in the graph of FIG. 6A show the results of simulation performed under the conditions of, in order from the bottom curve, 0.6 J/cm², 0.8 J/cm², 1.0 J/cm², 1.2 J/cm², 1.4 J/cm², 1.6 J/cm², and 1.8 J/cm². The curves in the graph of FIG. 6B show the results of simulation performed under the conditions of, in order from the bottom curve, 1.2 J/cm², 1.4 J/cm², 1.6 J/cm², 1.8 J/cm², 2.0 J/cm², 2.5 J/cm², and 3.0 J/cm². The curves in the graph of FIG. 6C show the results of simulation performed under the conditions of, in order from the bottom curve, 1.4 J/cm², 1.6 J/cm², 1.8 J/cm², 2.2 J/cm², 2.6 J/cm², 3.0 J/cm², and 3.4 J/cm². The curves in the graph of FIG. 6D show the results of simulation performed under the conditions of, in order from the bottom curve, 2.2 J/cm², 2.4 J/cm², 2.6 J/cm², 3.0 J/cm², 3.4 J/cm², 3.8 J/cm², and 4.2 J/cm².

From the simulation results shown in FIGS. 6A to 6D, the conditions of a fluence under which the maximum temperature of the interface becomes equal to the silicide reaction temperature RT of Ti is determined. For example, under the conditions in which the pulse width is 20 ns, 50 ns, 100 ns, and 200 ns, as shown in FIGS. 6A to 6D respectively, when the fluence is about 0.8 J/cm², about 1.3 J/cm², about 1.6 J/cm², and about 2.4 J/cm², the maximum temperature of the interface becomes equal to or higher than the silicide reaction temperature of Ti.

FIG. 6A to 6D show the simulation results of a temporal change of an interfacial temperature between a Ti film and a SiC substrate. The temporal change of a surface temperature of the Ti film can be determined by simulation under the same conditions. From the simulation results, the conditions of a fluence under which the maximum temperature of the surface of the Ti film does not exceed the melting point of Ti is determined.

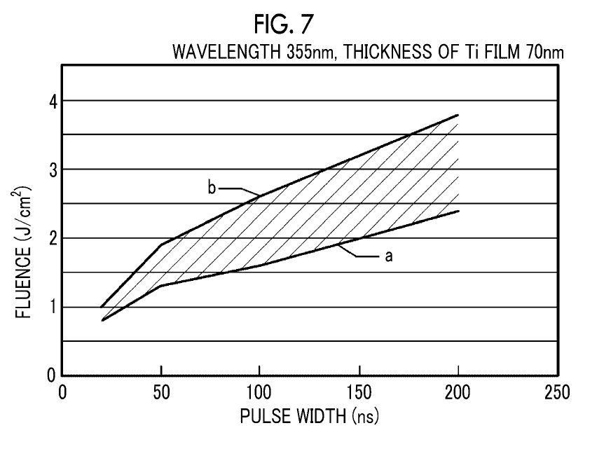

FIG. 7 shows the range of annealing conditions under which the maximum temperature of an interface between a Ti film and a SiC substrate becomes equal to or higher than the silicide reaction temperature of Ti, and the maximum temperature of the surface of the Ti film does not exceed the melting point of Ti. The abscissa shows a pulse width in the unit of “ns”, and the ordinate shows a fluence in the unit of “J/cm²”. Within the upper left region above a solid line a in the drawing, the maximum temperature of the interface between the Ti film and the SiC substrate becomes equal to or higher than the silicide reaction temperature of Ti. Within the lower right region below a solid line b in the drawing, the surface temperature of the Ti film does not exceed the melting point of Ti. Accordingly, the pulse width and the fluence within the hatched region between the solid line a and the solid line b satisfy the non-melting silicide conditions. Within a range of a pulse width of at least 20 ns to 200 ns, a fluence satisfying the aforementioned conditions can be selected.

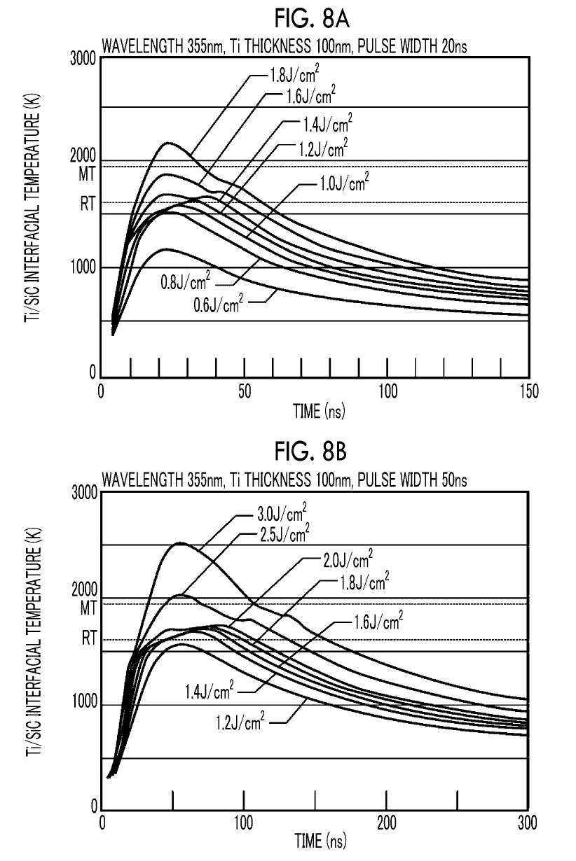

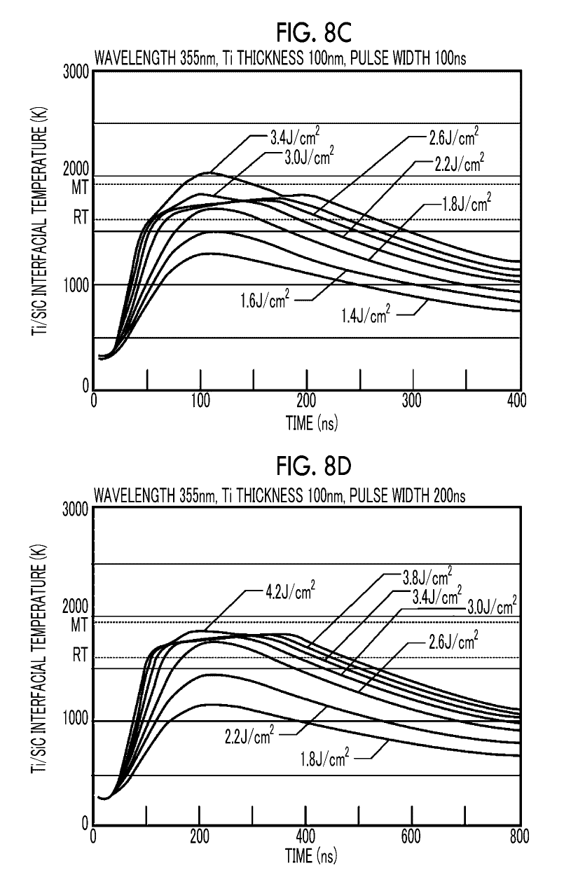

FIG. 8A to 8D each show the simulation results of a temporal change of an interfacial temperature between a Ti film and a SiC substrate that are obtained when laser annealing is performed under the conditions of a thickness of a Ti film of 100 nm. The wavelength and pulse width conditions of the simulation shown in FIG. 8A to 8D are the same as the wavelength and the pulse width conditions of the simulation shown in FIG. 6A to 6D respectively.

The curves in the graph of FIG. 8A show the results of simulation performed under the conditions of, in order from the bottom curve, 0.6 J/cm², 0.8 J/cm², 1.0 J/cm², 1.2 J/cm², 1.4 J/cm², 1.6 J/cm², and 1.8 J/cm². The curves in the graph of FIG. 8B show the results of simulation performed under the conditions of, in order from the bottom curve, 1.2 J/cm², 1.4 J/cm², 1.6 J/cm², 1.8 J/cm², 2.0 J/cm², 2.5 J/cm², and 3.0 J/cm². The curves in the graph of FIG. 8C show the results of simulation performed under the conditions of, in order from the bottom curve, 1.4 J/cm², 1.6 J/cm², 1.8 J/cm², 2.2 J/cm², 2.6 J/cm², 3.0 J/cm², and 3.4 J/cm². The curves in the graph of FIG. 8D show the results of simulation performed under the conditions of, in order from the bottom curve, 1.8 J/cm², 2.2 J/cm², 2.6 J/cm², 3.0 J/cm², 3.4 J/cm², 3.8 J/cm², and 4.2 J/cm².

From the simulation results shown in FIG. 8A to 8D, the conditions of a fluence under which the maximum temperature of the interface becomes equal to the silicide reaction temperature of Ti. For example, under the conditions of a pulse width of 20 ns, 50 ns, 100 ns, and 200 ns, as shown in FIG. 8A to 8D respectively, when the fluence is about 1.2 J/cm², about 1.3 J/cm², about 1.7 J/cm², and about 2.4 J/cm², the maximum temperature of the interface becomes equal to or higher than the silicide reaction temperature of Ti.

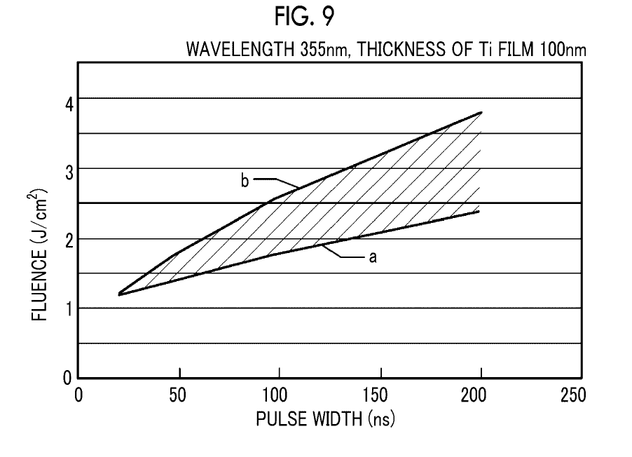

FIG. 9 shows the range of annealing conditions under which, when the thickness of the Ti film is 100 nm, the maximum temperature of the interface between a Ti film and a SiC substrate becomes equal to or higher than the silicide reaction temperature of Ti, and the maximum temperature of the surface of the Ti film does not exceed the melting point of Ti. The abscissa, the ordinate, the solid line a, and the solid line b of FIG. 9 have the same meaning as the abscissa, the ordinate, the solid line a, and the solid line b of FIG. 7 respectively. When the thickness of the Ti film is 100 nm, the pulse width and the fluence within the hatched region between the solid line a and the solid line b satisfy the non-melting silicide conditions. Within a range of a pulse width of at least 20 ns to 200 ns, a fluence satisfying the aforementioned conditions can be selected. When the pulse width is less than 20 ns, there is no fluence satisfying the non-melting silicide conditions.

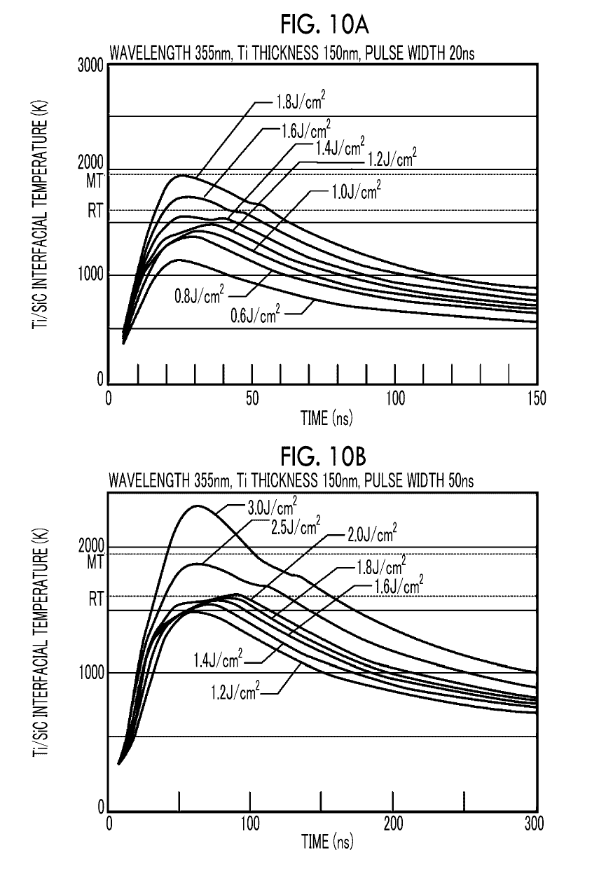

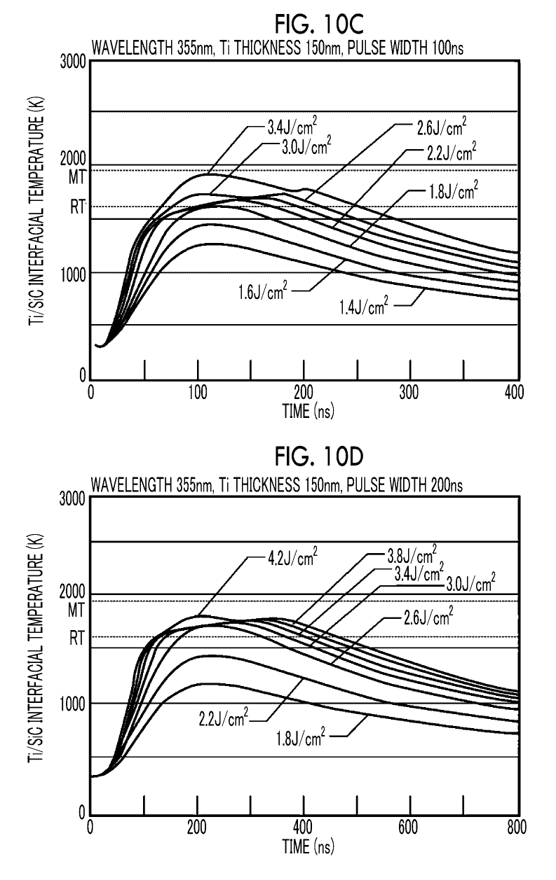

FIGS. 10A to 10D each show the simulation results of a temporal change of an interfacial temperature between a Ti film and a SiC substrate that are obtained when laser annealing is performed under the conditions of a thickness of a Ti film of 150 nm. The wavelength and pulse width conditions of the simulation shown in FIGS. 10A to 10D are the same as the wavelength and pulse width conditions of the simulation shown in FIGS. 6A to 6D respectively.

The curves in the graph of FIG. 10A show the results of simulation performed under the conditions of, in order from the bottom curve, 0.6 J/cm², 0.8 J/cm², 1.0 J/cm², 1.2 J/cm², 1.4 J/cm², 1.6 J/cm², and 1.8 J/cm². The curves in the graph of FIG. 10B show the results of simulation performed under the conditions of, in order from the bottom curve, 1.2 J/cm², 1.4 J/cm², 1.6 J/cm², 1.8 J/cm², 2.0 J/cm², 2.5 J/cm², and 3.0 J/cm². The curves in the graph of FIG. 10C show the results of simulation performed under the conditions of, in order from the bottom curve, 1.4 J/cm², 1.6 J/cm², 1.8 J/cm², 2.2 J/cm², 2.6 J/cm², 3.0 J/cm², and 3.4 J/cm². The curves in the graph of FIG. 10D show the results of simulation performed under the conditions of, in order from the bottom curve, 1.8 J/cm², 2.2 J/cm², 2.6 J/cm², 3.0 J/cm², 3.4 J/cm², 3.8 J/cm², and 4.2 J/cm².

From the simulation results shown in FIGS. 10A to 10D, the conditions of a fluence under which the maximum temperature of the interface becomes equal to the silicide reaction temperature of Ti is determined. For example, under the conditions of a pulse width of 20 ns, 50 ns, 100 ns, and 200 ns, as shown in FIGS. 10A to 10D respectively, when the fluence is about 1.6 J/cm², about 1.8 J/cm², about 1.8 J/cm², and about 2.6 J/cm², the maximum temperature of the interface becomes equal to or higher than the silicide reaction temperature of Ti.

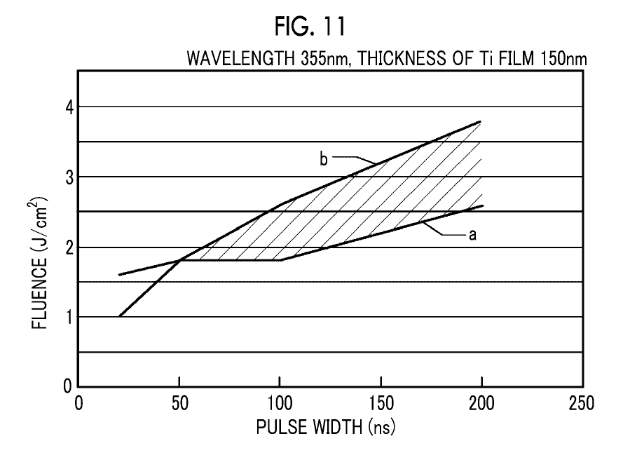

FIG. 11 shows the range of annealing conditions under which, when the thickness of a Ti film is 150 nm, the maximum temperature of an interface between the Ti film and a SiC substrate becomes equal to or higher than a silicide reaction temperature of Ti, and the maximum temperature of the surface of the Ti film does not exceed the melting point of Ti. The abscissa, the ordinate, the solid line a, and the solid line b of FIG. 11 have the same meaning as the abscissa, the ordinate, the solid line a, and the solid line b in FIG. 7 respectively. When the thickness of the Ti film is 150 nm, the pulse width and the fluence within the hatched region which is above the solid line a and is below the solid line b satisfy the non-melting silicide conditions. When the pulse width is less than 50 ns, there is no fluence satisfying the non-melting silicide conditions.

From the simulation results shown in FIGS. 7, 9, and 11, the following conclusions are drawn.

The thicker the Ti film, the greater the lower limit of the pulse width satisfying the non-melting silicide conditions. It was confirmed that, in a case where the thickness of the Ti film is within a range of 70 nm to 100 nm, if the pulse width is set to be within a range of 20 ns to 200 ns, a fluence exists which satisfies the non-melting silicide conditions. It was also confirmed that, in a case where the thickness of the Ti film is within a range of 100 nm to 150 nm, if the pulse width is set to be within a range of 50 ns to 200 ns, a fluence exists which satisfies the non-melting silicide conditions.

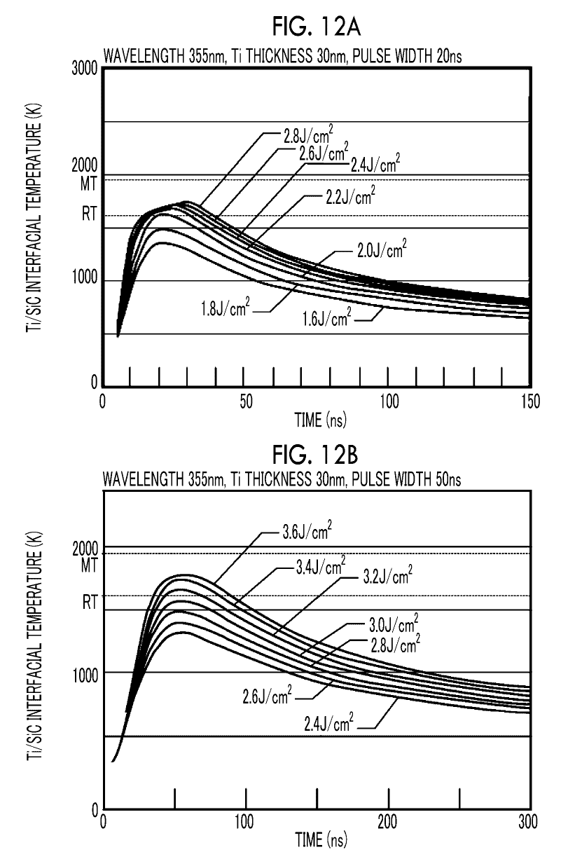

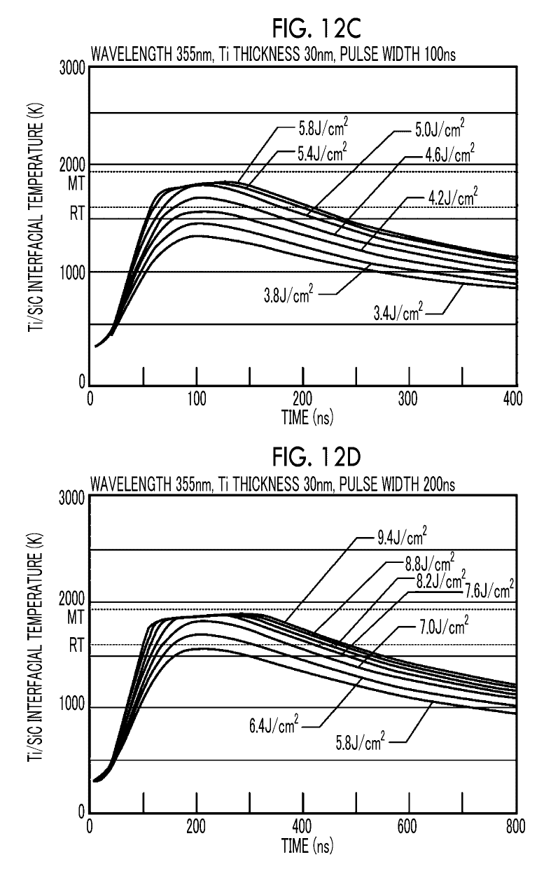

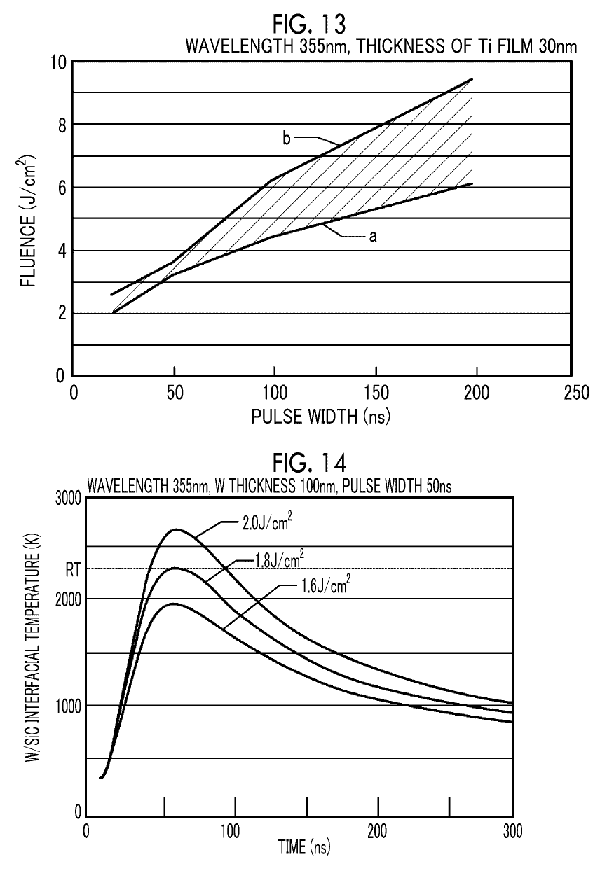

FIGS. 12A to 12D each show the simulation results of a temporal change of an interfacial temperature between a Ti film and a SiC substrate that are obtained when laser annealing is performed under the conditions of a thickness of a Ti film of 30 nm. The wavelength and pulse width conditions of the simulation shown in FIGS. 12A to 12D are the same as the wavelength and pulse width conditions of the simulation shown in FIGS. 6A to 6D respectively.

The curves in the graph of FIG. 12A show the results of simulation performed under the conditions of, in order from the bottom curve, 1.6 J/cm², 1.8 J/cm², 2.0 J/cm², 2.2 J/cm², 2.4 J/cm², 2.6 J/cm², and 2.8 J/cm². The curves in the graph of FIG. 12B show the results of simulation performed under the conditions of, in order from the bottom curve, 2.4 J/cm², 2.6 J/cm², 2.8 J/cm², 3.0 J/cm², 3.2 J/cm², 3.4 J/cm², and 3.6 J/cm². The curves in the graph of FIG. 12C show the results of simulation performed under the conditions of, in order from the bottom curve, 3.4 J/cm², 3.8 J/cm², 4.2 J/cm², 4.6 J/cm², 5.0 J/cm², 5.4 J/cm², and 5.8 J/cm². The curves in the graph of FIG. 12D show the results of simulation performed under the conditions of, in order from the bottom curve, 5.8 J/cm², 6.4 J/cm², 7.0 J/cm², 7.6 J/cm², 8.2 J/cm², 8.8 J/cm², and 9.4 J/cm².

From the simulation results shown in FIGS. 12A to 12D, the conditions of a fluence are determined under which the maximum temperature of the interface becomes equal to the silicide reaction temperature of Ti. For example, under the conditions of a pulse width of 20 ns, 50 ns, 100 ns, and 200 ns, as shown in FIGS. 12A to 12D respectively, when the fluence is about 2.0 J/cm², about 3.2 J/cm², about 4.4 J/cm², and about 6.1 J/cm², the maximum temperature of the interface becomes equal to or higher than the silicide reaction temperature of Ti.

FIG. 13 shows the range of annealing conditions under which, when the thickness of a Ti film is 30 nm, the maximum temperature of an interface between the Ti film and a SiC substrate becomes equal to or higher than the silicide reaction temperature of Ti, and the maximum temperature of the surface of the Ti film does not exceed the melting point of Ti. The abscissa, the ordinate, the solid line a, and the solid line b of FIG. 13 have the same meaning as the abscissa, the ordinate, the solid line a, and the solid line b of FIG. 7 respectively. When the thickness of the Ti film is 30 nm, the pulse width and the fluence within the hatched region which is above the solid line a and is below the solid line b satisfy the non-melting silicide conditions.

Through the comparison between the non-melting silicide conditions shown in FIGS. 7, 9, and 11 and the aforementioned non-melting silicide conditions, it is understood, in a case where the pulse width is the same, a great fluence is required, because the thinner the Ti film, the further the heat is scattered to the SiC substrate having higher thermal conductivity compared to the Ti film, and this makes it difficult for the temperature of the interface between the Ti film and the SiC substrate to increase. In a case where a great fluence is required for laser annealing, a high-power laser light source should be prepared. Accordingly, the cost of the laser annealing device increases. In order to inhibit the cost increase of the device, the thickness of the Ti film is preferably set to be equal to or greater than 30 nm and more preferably set to be equal to or greater than 70 nm.

The thicker the Ti film is, the greater the pulse width has to be, such that the surface is not melted and the interfacial temperature is increased up to the silicide reaction temperature of Ti. The maximum pulse width of the general Q-switched solid-state laser is limited, and it is difficult to increase the pulse width over 200 ns. Therefore, the thickness of the Ti film is preferably set to be equal to or less than 150 nm.

In the simulations and experiments described above, the wavelength of the pulsed laser beam was set to be 355 nm. If the wavelength of the pulsed laser beam changes, the reflectivity on the surface of the metal film 16 (FIG. 1E) also changes. In response to the change of the reflectivity, a preferred range of the fluence changes. Here, it is considered that, if the wavelength is within a range of 330 nm to 370 nm, a suitable range of the fluence practically does not change. Examples of the pulsed laser beam having a wavelength within a range of 330 nm to 370 nm include the third harmonic of solid-state laser such as a Nd:YAG laser, a Nd:YLF laser, a Nd:YVO₄ laser, an Yb:YAG laser, an Yb:YLF laser, and an Yb:YVO₄ laser.

FIG. 14 shows the simulation results of a temperature change of an interface between the metal film 16 and the substrate 10 that are obtained when laser annealing is performed using a tungsten (W) film having a thickness of 100 nm as the metal film 16 (FIG. 1E). The abscissa shows the time elapsing from the point of the rise time of the laser pulse in the unit of “ns”, and the ordinate shows the temperature of the interface between the W film and the SiC substrate in the unit of “K”. The curves of FIG. 14 show the temperature change at the time when the laser annealing is performed under the conditions in which the fluence within the surface of the W film is, in order from the bottom curve, 1.6 J/cm², 1.8 J/cm², and 2.0 J/cm². Although the silicide reaction temperature RT of W depends on the compositional ratio between W and Si, in order to cause a silicide reaction, a temperature of equal to or higher than 2,283 K is required. The melting point of W is 3,695 K. The pulsed laser beam has a wavelength of 355 nm and a pulse width of 50 ns.

It is understood that in a case where the fluence is set to be greater than 1.8 J/cm², the interfacial temperature between the W film and the SiC substrate exceeds the silicide reaction temperature RT of W. As a result of simulating the surface temperature of the W film under the aforementioned conditions, it was understood that the surface temperature of the W film does not exceed the melting point of W. In a case where W is used as the metal film 16 (FIG. 1E), the laser annealing conditions also exist under which the interfacial temperature exceeds the silicide reaction temperature, and the surface temperature does not exceed the melting point.

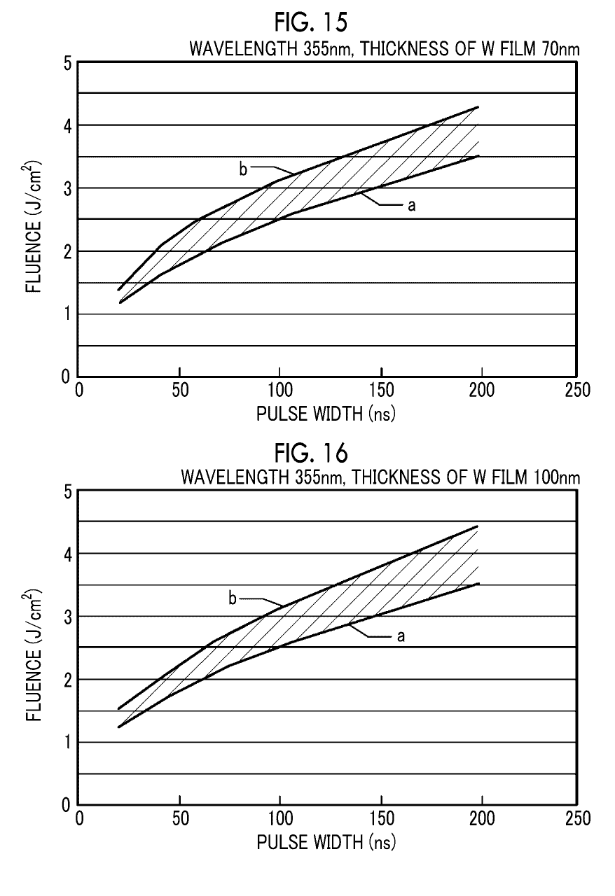

FIGS. 15, 16, and 17 show the range of annealing conditions under which, when the thickness of each W film is 70 nm, 100 nm, and 150 nm, the maximum temperature of the interface between the W film and the SiC substrate becomes equal to or higher than the silicide reaction temperature of W, and the maximum temperature of the surface of the W film does not exceed the melting point of W. The abscissa, the ordinate, the solid line a, and the solid line b of FIGS. 15 to 17 have the same meaning as the abscissa, the ordinate, the solid line a, and the solid line b of FIG. 7 respectively. It is understood that when the thickness of the W film is within a range of 70 nm to 150 nm, the annealing conditions exist which satisfy the non-melting silicide conditions.

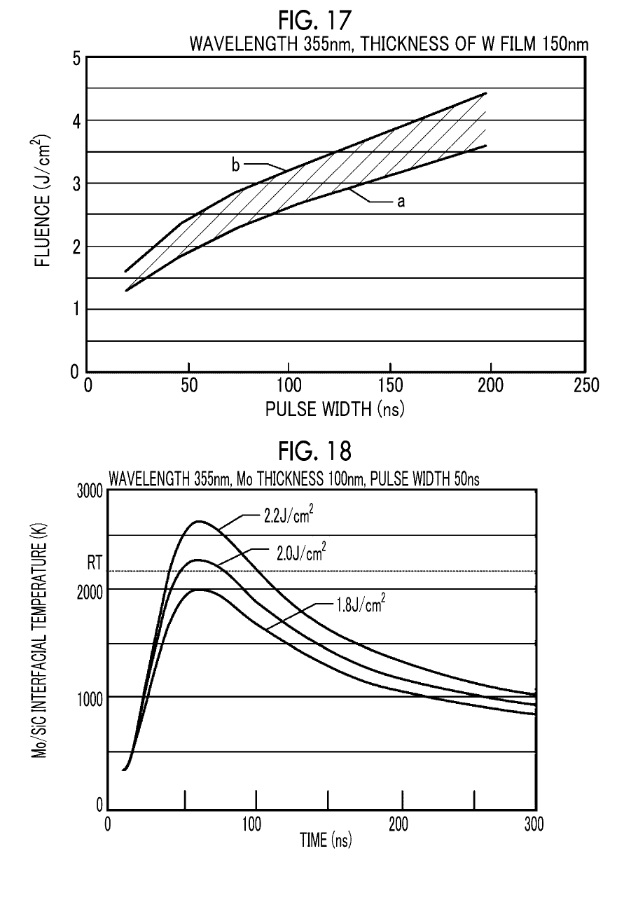

FIG. 18 shows the simulation results of a temperature change of an interfacial between the metal film 16 and the substrate 10 at the time of laser annealing performed using a molybdenum (Mo) film having a thickness of 100 nm as the metal film 16 (FIG. 1E). The abscissa shows the time elapsing from the point of the rise time of the laser pulse in the unit of “ns”, and the ordinate shows the temperature of the interface between the Mo film and a SiC substrate in the unit of “K”. The solid lines in FIG. 18 show a change of a temperature at the time of performing laser annealing under the conditions in which the fluence within the surface of the Mo film is, in order from the bottom line, 1.8 J/cm², 2.0 J/cm², and 2.2 J/cm². Although the silicide reaction temperature RT of Mo depends on the compositional ratio between Mo and Si, in order to cause the silicide reaction, a temperature of equal to or higher than 2,173 is required. The melting point of Mo is 2,896 K. The pulsed laser beam has a wavelength of 355 nm and a pulse width of 50 ns.

It is understood that in a case where the fluence is set to be greater than 2.0 J/cm², the interfacial temperature between the Mo film and the SiC substrate exceeds the silicide reaction temperature RT of Mo. As a result of simulating the surface temperature of the Mo film under the aforementioned conditions, it was understood that the surface temperature of the Mo film does not exceed the melting point of W. In a case where Mo is used as the metal film 16 (FIG. 1E), the laser annealing conditions also exist under which the interfacial temperature exceeds the silicide reaction temperature, and the surface temperature does not exceed the melting point.

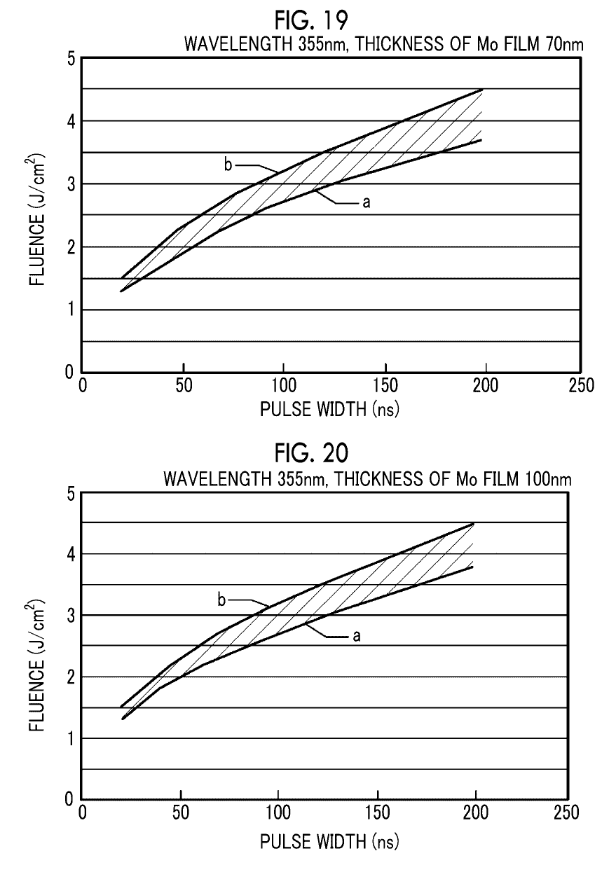

FIGS. 19, 20, and 21 show the range of annealing conditions under which, when the thickness of each Mo film is 70 nm, 100 nm, and 150 nm, the maximum temperature of the interface between the Mo film and a SiC substrate becomes equal to or higher than the silicide reaction temperature of Mo, and the maximum temperature of the surface of the Mo film does not exceed the melting point of Mo. The abscissa, the ordinate, the solid line a, and the solid line b of FIGS. 19 to 21 have the same meaning as the abscissa, the ordinate, the solid line a, and the solid line b of FIG. 7 respectively. It is understood that when the thickness of the Mo film is within a range of 70 nm to 150 nm, the annealing conditions exist which satisfy the non-melting silicide conditions.

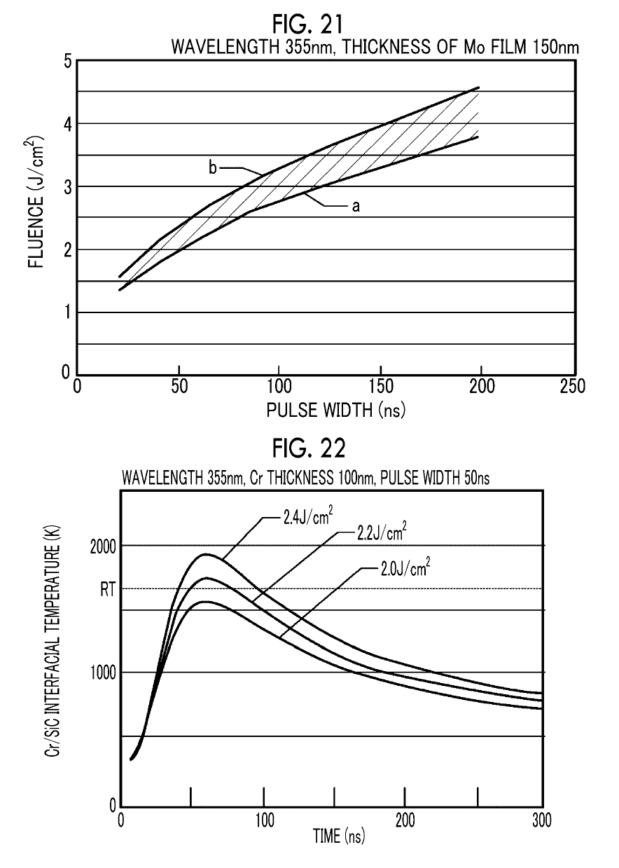

FIG. 22 shows the simulation results of a temperature change of an interface between the metal film 16 and the substrate 10 at the time of laser annealing performed using a chromium (Cr) film having a thickness of 100 nm as the metal film 16 (FIG. 1E). The abscissa shows the time elapsing from the point of the rise time of the laser pulse in the unit of “ns”, and the ordinate shows the temperature of the interface between the Cr film and a SiC substrate in the unit of “K”. The curves in FIG. 22 show a temperature change at the time of performing laser annealing under the conditions in which the fluence within the surface of the Cr film is, in order from the bottom line, 2.0 J/cm², 2.2 J/cm², and 2.4 J/cm². Although the silicide reaction temperature RT of Cr depends on the compositional ratio between Cr and Si, in order to cause the silicide reaction, a temperature of equal to or higher than 1,663 is required. The melting point of Cr is 2,180 K. The pulsed laser beam has a wavelength of 355 nm and a pulse width of 50 ns.

It is understood that, in a case where the fluence is set to be greater than 2.2 J/cm², the interfacial temperature between the Cr film and the SiC substrate exceeds the silicide reaction temperature RT of Cr. As a result of simulating the surface temperature of the Cr film under the aforementioned conditions, it is understood that the surface temperature of the Cr film does not exceed the melting point of Cr. In a case where Cr is used as the metal film 16 (FIG. 1E), the laser annealing conditions also exist under which the interfacial temperature exceeds the silicide reaction temperature, and the surface temperature does not exceed the melting point.

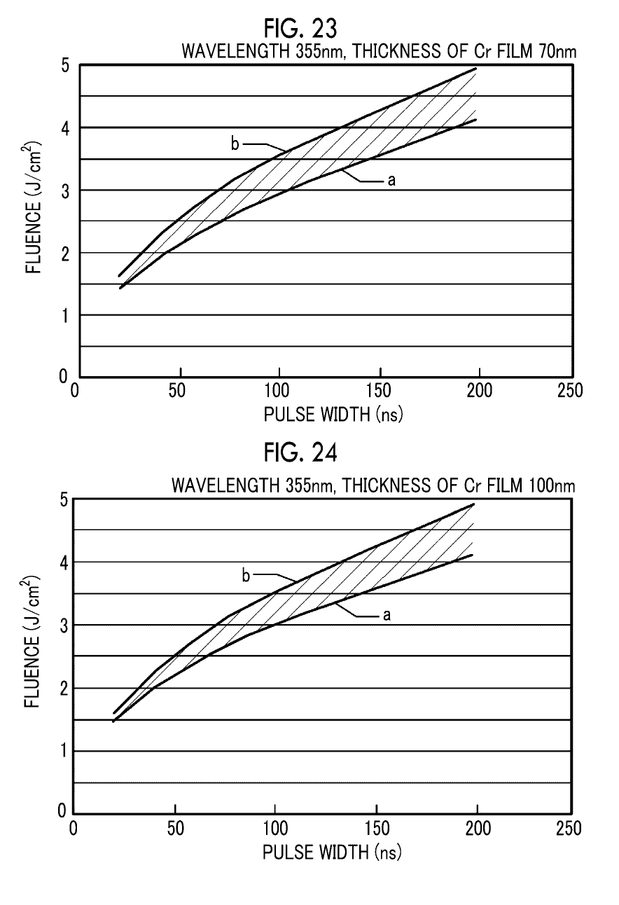

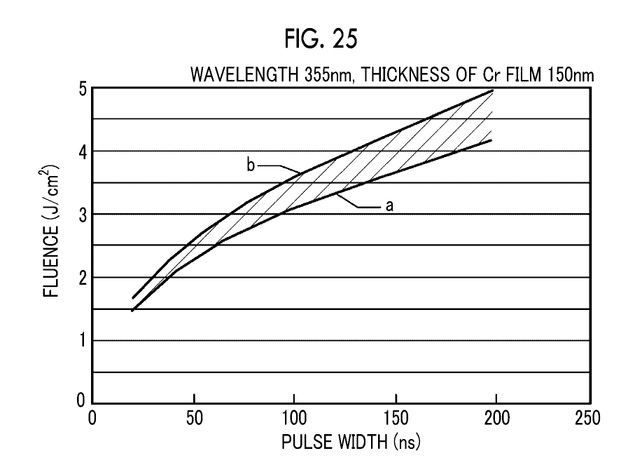

FIGS. 23, 24, and 25 show the range of annealing conditions under which, when the thickness of each Cr film is 70 nm, 100 nm, and 150 nm, the maximum temperature of the interface between the Cr film and the SiC substrate becomes equal to or higher than the silicide reaction temperature of Cr, and the maximum temperature of the surface of the Cr film does not exceed the melting point of Cr. The abscissa, the ordinate, the solid line a, and the solid line b of FIGS. 23 to 25 have the same meaning as the abscissa, the ordinate, the solid line a, and the solid line b of FIG. 7 respectively. It is understood that when the thickness of the Cr film is within a range of 70 nm to 150 nm, the annealing conditions exist which satisfy the non-melting silicide conditions.

As shown in FIGS. 14 to 25, as the metal film 16 (FIG. 1E), W, Mo, or Cr can also be used. In this case, it is preferable to make the wavelength of the pulsed laser beam fall into a range of 330 nm to 370 nm as in the case where Ti is used. In order to reduce the scattering of heat to the SiC substrate, the thickness of the W film, the Mo film, and the Cr film is preferably set to be equal to or greater than 30 nm, and more preferably set to be equal to or greater than 70 nm.

In a case where W, Mo, or Cr is used as the metal film 16 (FIG. 1E), it is preferable to select the pulse width of the pulsed laser beam within a range of 20 ns to 200 ns as in the case where the Ti film is used. The fluence may be selected within the aforementioned range of the pulse width, such that the maximum temperature of the surface of the metal film 16 (FIG. 1E) exceeds the melting point of the metal film 16, and the maximum temperature of the interface between the metal film 16 and the substrate 10 becomes equal to or higher than the silicide reaction temperature of the metal film.

Hitherto, the present invention has been described based on examples, but the present invention is not limited thereto. For example, those in the related art may know for sure that various modification, ameliorations, combinations, and the like can be made.

It should be understood that the invention is not limited to the above-described embodiment, but may be modified into various forms on the basis of the spirit of the invention. Additionally, the modifications are included in the scope of the invention.

What is claimed is:

1. A method for manufacturing a semiconductor element, comprising:
forming a metal film, which contains at least one metal selected from the group consisting of titanium, tungsten, molybdenum, and chromium, on a first surface of a substrate formed of silicon carbide; and
forming a metal silicide film by causing a silicide reaction within an interface between the substrate and the metal film by irradiating the metal film with a pulsed laser beam having a wavelength within a range of 330 nm to 370 nm,
wherein a thickness of the metal film is equal to or greater than 30 nm,
a pulse width of the pulsed laser beam is within a range of 20 ns to 200 ns, and
a fluence is selected so as to satisfy conditions under which a maximum temperature of a surface of the metal film does not exceed a melting point of the metal film and a maximum temperature of the interface between the metal film and the substrate becomes equal to or higher than a silicide reaction temperature of the metal film.

2. The method for manufacturing a semiconductor element according to claim 1,
wherein the metal film is formed of titanium, and
the thickness of the metal film is within a range of 70 nm to 100 nm.

3. The method for manufacturing a semiconductor element according to claim 1,
wherein the metal film is formed of titanium,
the thickness of the metal film is within a range of 100 nm to 150 nm, and
the pulse width of the pulsed laser beam is within a range of 50 ns to 200 ns.

4. The method for manufacturing a semiconductor element according to claim 1,
wherein the metal film is formed of one metal selected from the group consisting of tungsten, molybdenum, and chromium, and
the thickness of the metal film is within a range of 70 nm to 150 nm.

5. The method for manufacturing a semiconductor element according to claim 1,
wherein the pulsed laser beam is third harmonic of one solid-state laser selected from the group consisting of a Nd:YAG laser, a Nd:YLF laser, a Nd:YVO₄ laser, an Yb:YAG laser, an Yb:YLF laser, and an Yb:YVO₄ laser.

6. A semiconductor element comprising:
a substrate formed of silicon carbide;
a metal film which is formed on a first surface of the substrate and contains at least one metal selected from the group consisting of titanium, tungsten, molybdenum, and chromium; and
a metal silicide film formed by causing a silicide reaction within an interface between the substrate and the metal film by irradiating the metal film with a pulsed laser beam having a wavelength within a range of 330 nm to 370 nm,
wherein a thickness of the metal film is equal to or greater than 30 nm,
a pulse width of the pulsed laser beam is within a range of 20 ns to 200 ns, and
a fluence is selected so as to satisfy conditions under which a maximum temperature of a surface of the metal film does not exceed a melting point of the metal film and a maximum temperature of the interface between the metal film and the substrate becomes equal to or higher than a silicide reaction temperature of the metal film.

7. The semiconductor element according to claim 6,
wherein the metal film is formed of titanium, and
the thickness of the metal film is within a range of 70 nm to 100 nm.

8. The semiconductor element according to claim 6,
wherein the metal film is formed of titanium,
the thickness of the metal film is within a range of 100 nm to 150 nm, and
the pulse width of the pulsed laser beam is within a range of 50 ns to 200 ns.

9. The semiconductor element according to claim 6,
wherein the metal film is formed of one metal selected from the group consisting of tungsten, molybdenum, and chromium, and
the thickness of the metal film is within a range of 70 nm to 150 nm.

10. The semiconductor element according to claim 6,
wherein the pulsed laser beam is third harmonic of one solid-state laser selected from the group consisting of a Nd:YAG laser, a Nd:YLF laser, a Nd:YVO₄ laser, an Yb:YAG laser, an Yb:YLF laser, and an Yb:YVO₄ laser.

11. An apparatus for manufacturing a semiconductor element, comprising:
a metal film forming portion that forms a metal film, which contains at least one metal selected from the group consisting of titanium, tungsten, molybdenum, and chromium, on a first surface of a substrate formed of silicon carbide; and
a metal silicide film forming portion that forms a metal silicide film by causing a silicide reaction within an interface between the substrate and the metal film by irradiating the metal film with a pulsed laser beam having a wavelength within a range of 330 nm to 370 nm,
wherein a thickness of the metal film is equal to or greater than 30 nm,
a pulse width of the pulsed laser beam is within a range of 20 ns to 200 ns, and
a fluence is selected so as to satisfy conditions under which a maximum temperature of a surface of the metal film does not exceed a melting point of the metal film and a maximum temperature of the interface between the metal film and the substrate becomes equal to or higher than a silicide reaction temperature of the metal film.
